(19) United States
(12) Patent Application Publication
(10) Pub. No.: US 2008/0085474 A1
(43) Pub. Date: Apr. 10, 2008

(54) EXPOSURE METHOD USING NEAR FIELD LIGHT AND PATTERN FORMATION METHOD USING THE METHOD

(75) Inventors: Natsuhiko Mizutani, Tokyo (JP); Toshiki Ito, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/861,711

(22) Filed: Sep. 26, 2007

(30) Foreign Application Priority Data
Oct. 10, 2006 (JP) 2006-276078

(51) Int. Cl. G03F 7/20

(52) U.S. Cl. 430/322

(57) ABSTRACT

Provided is an exposure method using near field light which can form a pattern finer than a mask pitch and avoid difficulty when forming a mask for fine lithography at unity magnification. The exposure method is configured such that a mask including a light shielding film with a fine opening less in size than a wavelength of exposure light is closely contacted with a photosensitive thin film including a silane coupling agent on a substrate, and light of a wavelength at which the photosensitive thin film has sensitivity for propagating light is irradiated to perform exposure, wherein the exposure is performed with the light at such an exposure amount that an exposed portion in the photosensitive thin film just below an edge portion of the light shielding film and a non-exposed portion in the photosensitive thin film just below a central portion of the fine opening are formed coexistently.

### BACKGROUND OF THE INVENTION

1. Field of the Invention

The present invention relates to an exposure method using near field light and a pattern formation method using the method.

2. Description of the Related Art

Accompanied with the development of a high-capacity semiconductor memory and the development of high-speed or highly integrated CPU, finer photolithography has become indispensable.

In general, the lower limit of fine processing in a photolithographic apparatus is about the wavelength of a light source used. Therefore, the shortening of the wavelength has been attempted by using, for example, a near ultraviolet laser for the light source of a photolithographic apparatus, and it is now possible to perform fine processing of about 50 nm.

Although the finer photolithography has been developed as described above, with the shortening of the wavelength of a light source, there are still many unsolved problems, such as increase in the size of an apparatus, development of a lens for such a shorter wavelength, and the like.

In recent years, as one method to solve the problems, a near field light exposure method has been proposed. For example, International Publication No. WO2005/001569 proposes a method in which the entire surface of a mask is brought into close contact with a resist surface and one-shot exposure is performed using optical near field to thereby form a resist pattern arranged with the same pitch as a mask pattern.

Japanese Patent Application Laid-Open No. 2004-235574 discloses a method of forming a resist pattern in which non-resonant light of an energy lower than an intermolecular resonant energy is irradiated to a photo mask to generate near field light in a region of a nanometer size, thereby exposing a resist film.

This patent publication discloses that the near field light is generated at an edge portion of a mask shielding film and a resist pattern corresponding thereto is formed.

Meanwhile, in the photolithography which is now becoming finer, further improvement is desired.

For example, in the mask one-shot exposure using near field light disclosed in International Publication No. WO2005/001569 above, in order to perform fine lithography at unity magnification, a complicated and highly controllable process is required for formation of a mask.

In the lithography using non-resonant light disclosed in Japanese Patent Application Laid-Open No. 2004-235574, there is a problem that the utilization efficiency of irradiation light is low, and the throughput of the process cannot be increased.

### SUMMARY OF THE INVENTION

The present invention provides a light exposure method using near field light and a pattern formation method which can form a resist pattern finer than a pitch of a mask, thereby to avoid the difficulty involved with the formation of a mask which allows fine lithography at unity magnification.

The exposure method using near field light provided by the present invention is an exposure method using near field light in which an exposure mask including a light shielding film having formed therein a fine opening which is less in size than a wavelength of exposure light is brought into close contact with a photosensitive thin film including a silane coupling agent formed on a substrate, and light of a wavelength at which the photosensitive thin film has sensitivity for propagating light is irradiated, thereby performing exposure, wherein when the exposure mask is irradiated with the light to perform the exposure, the exposure is performed at such an exposure that an exposed portion in the photosensitive thin film just below an edge portion of the light shielding film having the fine opening formed therein and a non-exposed portion in the photosensitive thin film just below a central portion of the fine opening are formed coexistently.

The pattern formation method according to the present invention is characterized in that a pattern is formed by distributing metal atom containing fine particles into an exposed portion of a photosensitive thin film formed by employing the exposure method using near field light of the present invention.

According to the present invention, a pattern which is finer than a pitch of a mask can be formed, so that the difficulty involved with the formation of a mask which allows fine lithography at unity magnification can be avoided.

Further features of the present invention will become apparent from the following description of exemplary embodiments with reference to the attached drawings.

### BRIEF DESCRIPTION OF THE DRAWINGS

FIGS. 1A, 1B, 1C, 1D, and 1E are views illustrating steps of lithography in an embodiment of the present invention.

FIG. 2 is a graphical representation illustrating a calculation example of photoreaction ratios at a location just below an edge portion of a light shielding film and at a location just below a center of a mask opening portion of a mask relative to exposure time in an embodiment of the present invention.

FIGS. 3A, 3B, 3C, and 3D are views each illustrating a relationship between a pattern shape of exposure and a distribution state of fine particles in an embodiment of the present invention.

### DESCRIPTION OF THE EMBODIMENTS

The process of lithography according to an embodiment of the present invention will be described.

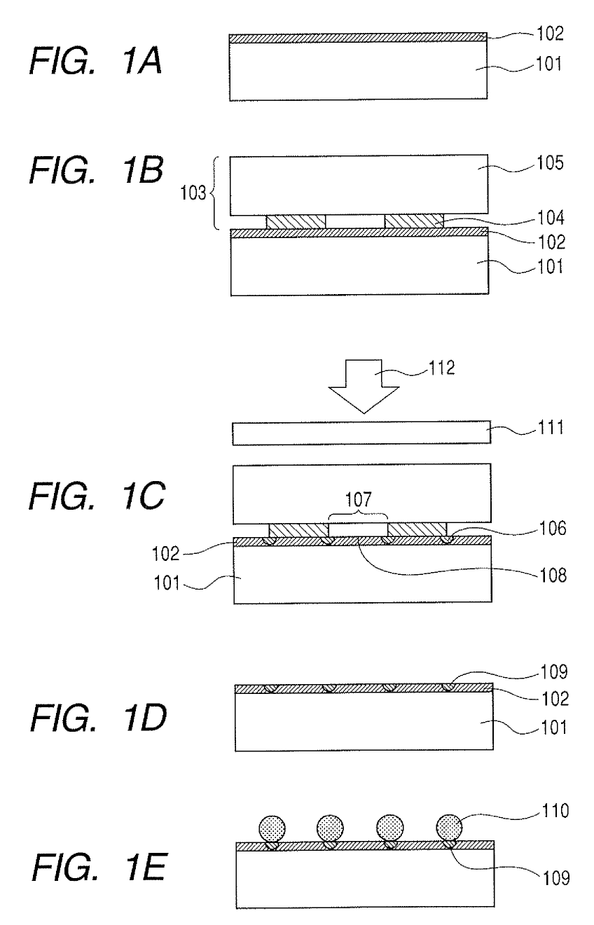

FIGS. 1A, 1B, 1C, 1D and 1E are views illustrating a process of lithography according to the present embodiment.

In FIGS. 1A, 1B, 1C, 1D and 1E, there are shown a substrate 101, a photosensitive thin film 102, and a photo mask for near field exposure.

There are also shown a light shielding film 104 of the photo mask, a base material 105 of the photo mask, a location 106 which is positioned just below an edge portion of the light shielding film having an opening formed therein, an opening portion 107 formed in the light shielding film, and a location 108 corresponding to the center of the photo mask opening potion.

Further, there are also shown a portion 109 in which a functional group is exposed (revealed) by light exposure and metal fine particles 110.

Moreover, there are also shown a band pass filter 111 and an illumination light used for the exposure.

According to the present embodiment, the near field light exposure photo mask 103 includes at least the light shielding material 104 of the photo mask and the base material 105 of the photo mask.

The location 106 in the photosensitive thin film 102 is positioned just below an edge portion of the light shielding film having the opening formed therein of the photo mask 103.

In the light shielding film 104 of the photo mask 103, there is formed an opening 107 which is less in size than the wavelength of exposure light.

When performing the lithography of the present embodiment, first, the photosensitive thin film 102 is formed on the substrate 101 (FIG. 1A). At this time, it is preferable that as the photosensitive thin film, for example, a silane coupling agent is fixed to the substrate through chemical bonding.

Here, as the substrate, there can be used a wide variety of substrates including a semiconductor substrate such as of Si, GaAs or InP, an insulating substrate such as of glass, quartz or BN, or a substrate obtained by depositing at least one of resists, metals, oxides, nitrides, and the like on the above-mentioned substrate.

Above all, it is preferable that on a surface to which a silane coupling agent is fixed, a hydroxyl group is provided.

To provide a hydroxyl group on a substrate surface, a pretreatment of the substrate is performed as needed.

The pretreatment is performed by exposing a substrate surface to an acid solution or UV/ozone atmosphere.

As the acid for solution, there are included sulfuric acid, hydrochloric acid, nitric acid, hydrogen peroxide, and the like. Although these may be used singularly or in combination, the combined use of sulfuric acid and hydrogen peroxide is preferable.

The combined use of sulfuric acid and hydrogen peroxide is particularly suitable for the pretreatment of a Si substrate. As the means for the pretreatment using the acid solution, there are included, for example, coating, spraying, and dipping.

On the substrate, a silane coupling agent is coated and heated to form a silane coupling agent layer.

The coating of a silane coupling agent can be performed by using a liquid of a silane coupling agent alone or a solution having a silane coupling agent dissolved in an organic solvent, by means of dipping, spin coating, spray coating, vapor phase deposition, and the like.

In the present embodiment, dipping or spin coating is preferable. It is preferable that after the coating of a silane coupling agent, the agent is appropriately heated to terminate the reaction thereof with hydroxyl groups on the substrate. The heating is performed by using a heating means such as a hot plate or a hot air dryer at a temperature of 80° C. to 200° C., preferably 80° C. to 150° C. By the above-mentioned treatment, a monomolecular layer of the silane coupling agent is formed.

Here, examples of the silane coupling agent include those compounds which have a structure, prior to the exposure, such that thiol groups, amino groups, hydroxyl groups, carboxyl groups, or sulfo groups are protected by photodegradable protective groups and generate the functional groups by the exposure. Specifically, o-nitrobenzyl ethers or o-nitrobenzyl esters, or benzoin ethers or benzoin esters of the above-mentioned silane coupling agent containing the functional groups are preferable. It is known that such compounds are decomposed by light exposure to regenerate functional groups.

Next, the near field exposure mask 103 is brought into close contact with the substrate 101 having the photosensitive thin film 102 formed thereon (FIG.1B). This is performed by holding the substrate 101 on a wafer stage of an exposure apparatus (not shown) and holding the exposure mask 103 by a mask chuck, and then bringing the both members close to each other.

Subsequently, the light 112 from the light source is irradiated from above the mask for a predetermined period of time thereby exposing the photosensitive thin film 102 (FIG. 1C).

Here, the wavelength of the light source is selected from the wavelengths at which the photosensitive thin film material has sensitivity for propagating light.

At this time, in order to control the spectrum of the irradiated light and to thereby use light of a specified wavelength only, it is useful to allow the irradiated light to pass through a wavelength filter.

When an i-ray, a g-ray or the like of a mercury lamp is used in combination with a wavelength filter, an effective and stable light can be obtained relatively easily.

Incidentally, between the light source and the mask, no polarizing filter is inserted, and no polarization control is performed.

In the photosensitive thin film which has been brought into close contact with the mask and radiated by the light, an optical near field corresponding to the pattern of the light shielding film of the mask is generated.

It has been known that this optical near field very close to the mask is subjected to enhancement of the electric field strength particularly in an edge portion of the light shielding film.

This is an electric field enhancement effect due to the shape of the edge portion of the light shielding film.

This enhancement effect is exhibited particularly when irradiated by light with such polarization that the electric field component is perpendicular to this edge portion, and is not exhibited when irradiated by such polarized light that the electric field component is parallel to the edge.

Here, specifically, description will be made by taking, as an example, the case where the light shielding pattern of the mask is repeated line and space patterns in different directions for respective portions of the mask.

In this case, a polarization component which is in a direction perpendicular to the longitudinal direction of the line and space, that is, in a direction perpendicular to the edge contributes to the enhancement of the electric field, and a component which is parallel to the longitudinal direction does not contribute to the enhancement of the electric field.

For each portion, a polarization component corresponding to the direction of a local pattern at that portion is determined in self-adjusting fashion, and the augmentation of the electric field is caused by that component, so that the polarization control by means of an illumination system to illumine the entire mask is not required.

Thus, in the near field mask having a fine opening, at two locations of a location just below the edge portion of the light shielding film subjected to the enhancement effect and another location just below the center of the mask opening portion, the light intensities when illuminated are different from each other, and photoreactions of the photosensitive film proceed at reaction rates corresponding thereto.

The photoreaction process of the protected silane coupling agent is typically described as a first order reaction process.

The reaction equation regarding a protection ratio R is represented as follows with the spatial distribution of light intensity just below the mask being taken as I(x).

dR/dt=−R k φ I (x)

Here, k is a reaction constant, and φ is a reaction yield.

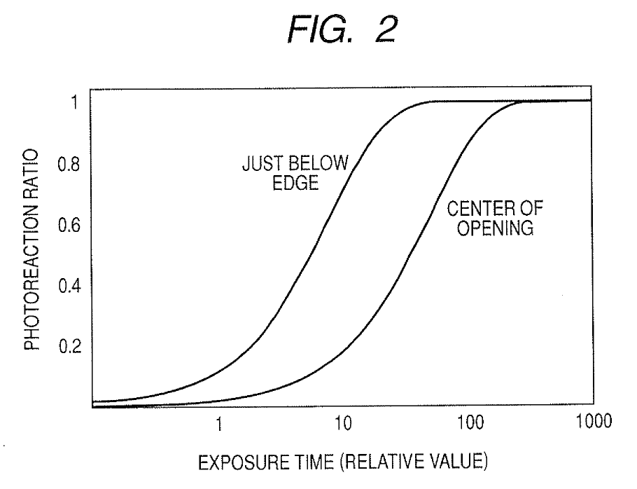

FIG. 2 illustrates a calculation example of photoreaction ratios at a location just below an edge portion of the light shielding film and at a location just below the center of the mask opening portion relative to exposure time.

Here, the photoreaction ratio indicated by the ordinate is an amount represented by (1-R) for the protection ratio R. The abscissa indicates the time on a logarithmic scale.

Incidentally, FIG. 2 is a calculation example in the case where the ratio of the light intensity at a location just below the edge portion of the light shielding film and the light intensity at a location just below the center of the mask opening portion is 6.

When selecting the exposure amount, the difference between the progress of the photoreaction just below the edge portion of the light shielding film and the progress of the photoreaction at the center of the opening portion is made large with reference to FIG. 2.

In the present invention, the photoreaction ratio just below the edge portion is made large, and the photoreaction ratio just below the center of the opening portion is made small, thereby making the difference between the both ratios relatively large, so that an exposed portion is generated just below the edge portion and a non-exposed portion is generated just below the center of the opening portion, with the result that the exposed portion and the non-exposed portion coexist.

Further, it is desirable to select such an exposure time that the contrast of the degrees of progress of the photoreaction in the surface of the photosensitivity thin film after the exposure is formed to a great extent.

Specifically, by giving an exposure amount exceeding 50% in photoreaction ratio at least in the region where the light intensity at the location just below the edge portion of the light shielding film is high, a region where the photoreaction proceeds can be surely formed just below the edge.

Alternatively, by setting the upper limit of the exposure time to such an exposure amount that the photoreaction ratio at the location just below the center of the opening portion does not exceed 50%, the photoreaction at the central portion is prevented from proceeding.

The photoreaction ratio corresponds to the density of the deprotected functional groups of the silane coupling agent that forms the photosensitive thin film.

For this functional group density, the contrast of the functional group density is defined from the maximum value dmax and the minimum value dmin at a location just under the opening portion as follows.

C=(dmax−dmin)/(dmax+dmin)

When the deprotection reaction is a first order reaction process, this contrast becomes a function which is simply reduced relative to the exposure amount, so that within the exposure amount range shown above, the side with less exposure amount is advantageous in terms of the contrast.

Specifically, a region which is within the region located just below the edge portion of the light shielding film and being high in the light intensity and which gives a photoreaction ratio of 50% to 80% provides the optimum exposure amount when considering the contrast of the functional group density of the surface. Here, the photoreaction ratio at a location just below the center of the opening portion is, for example, 10% to 20%, and with this exposure amount, the portion just below the center of the opening portion corresponds to a non-exposed portion.

With such exposure amount, the exposure is completed to form an exposed portion 109 in the photosensitive thin film 102 on the substrate 101 (FIG. 1D).

Since by-products are also formed in the exposed portion, the substrate subjected to the exposure is dipped into an organic solvent as needed to remove the by-products.

Next, the substrate subjected to the exposure is dipped into a colloidal solution in which fine particles containing metal atoms are dispersed.

By this step, the metal atom containing fine particles are deposited selectively only to the exposed portion of the substrate (FIG. 1E).

When a compound that generates thiol on light exposure is used for the silane coupling agent of the photosensitive thin film, as the metal atom containing fine particles, gold fine particles, gold nanorods, and fine particles having maleimide groups at terminals thereof can be preferably used.

These fine particles are advantageously selected and used because a gold atom and a thiol group, and a maleimide group and a thiol group easily react with each other, respectively, so that a strong covalent bond can be formed.

The type of the metal atom containing fine particles is selected depending on a device to be produced.

When a single electronic device is to be produced, conductive fine particles such as of metal or metal oxide are used.

When a magnetic recording medium such as a patterned media is to be produced, magnetic fine particles are used, or magnetization is performed after adhesion of fine particles of ferromagnetic metal.

When a chemical sensor is to be produced, metal fine particles are used. From the viewpoint of sensitivity and chemical stability, noble metal fine particles are preferable, and gold fine particles and gold nanorods are particularly preferable.

When a quantum dot laser device is to be produced, there are used, for example, semiconductor fine particles such as of GaAs, InGaAs, GaN, InP, and InAs.

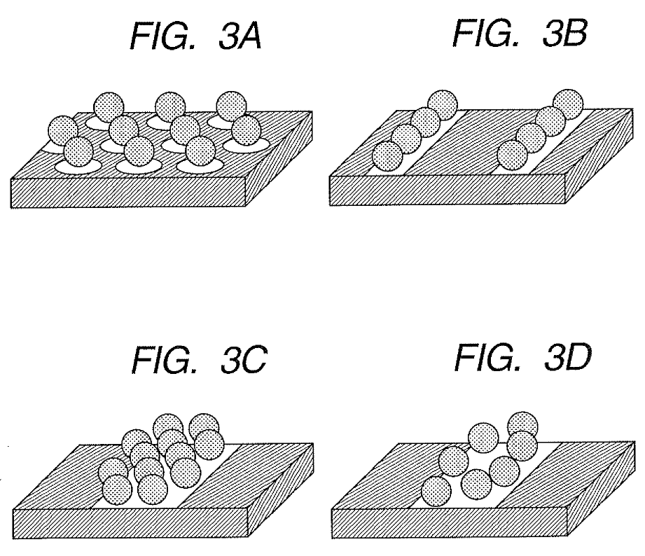

FIGS. 3A, 3B, 3C, and 3D each illustrate a relationship between a pattern shape of exposure and a distribution state of fine particles in the present embodiment. As the pattern shape in the present embodiment, an isolated dot pattern can be adopted in which a single fine particle is adhered to each one of fine dot-shaped exposed portions (FIG. 3A).

Alternatively, an isolated line pattern can be adopted in which fine particles are arranged in a line on a small-width line-shaped exposed portion (FIG. 3B).

Alternatively, a close packed pattern can be adopted in which fine particles are most closely packed on an exposed portion that is larger in size than the fine particle (FIG. 3C).

Alternatively, a random pattern can be adopted in which fine particle are randomly arranged at intervals of at least a predetermined distance by a repulsive force between the fine particles on an exposed portion that is larger in size than the fine particle (FIG. 3D).

As described above, the pattern shape can be freely formed depending on a device to be produced, and the formed patterns are not limited to the shapes as described above.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application 2006-276078, filed Oct. 10, 2006, which is hereby incorporated by reference herein in its entirety.

What is claimed is:

1. An exposure method using near field light in which an exposure mask comprising a light shielding film having formed therein a fine opening which is less in size than a wavelength of exposure light is brought into close contact with a photosensitive thin film comprising a silane coupling agent formed on a substrate, and light of a wavelength at which the photosensitive thin film has sensitivity for propagating light is irradiated, thereby performing exposure, wherein when the exposure mask is irradiated with the light to perform the exposure, the exposure is performed at such an exposure that an exposed portion in the photosensitive thin film just below an edge portion of the light shielding film having the fine opening formed therein and a non-exposed portion in the photosensitive thin film just below a central portion of the fine opening are formed coexistently.

2. The exposure method according to claim 1, wherein a photoreaction ratio of the photosensitive thin film just below the edge portion of the light shielding film having the fine opening formed therein is 50% or more.

3. The exposure method according to claim 1, wherein a photoreaction ratio of the photosensitive thin film just below the edge portion of the light shielding film having the fine opening formed therein is 50% or more and 80% or less.

4. The exposure method according to claim 1, wherein a photoreaction ratio of the photosensitive thin film just below a central portion of the fine opening is less than 50%.

5. A pattern formation method, which comprises disposing metal atom containing fine particles on an exposed portion of a photosensitive thin film formed by employing the exposure method using near field light set forth in claim 1, thereby forming a pattern.

6. The pattern formation method according to claim 5, wherein the metal atom containing fine particles are one of magnetic fine particles, fine particles of a ferromagnetic metal, metal fine particles, and semiconductor fine particles.

7. The pattern formation method according to claim 5, wherein the shape of the pattern is one of an isolated dot pattern, an isolated line pattern, a close packed pattern, and a random pattern.
